(19) United States
(12) Patent Application Publication
(10) Pub. No.: US 2002/0145856 A1
(43) Pub. Date: Oct. 10, 2002

(54) Small form-factor pluggable transceiver cage

(76) Inventors: Dennis B. Jones, Orange, CA (US); Eddy Wong, Cypress, CA (US)

Correspondence Address: WEI TE CHUNG, FOXCONN INTERNATIONAL, INC., 1650 MEMOREX DRIVE, SANTA CLARA, CA, 95050, US

(21) Appl. No.: 09/827,859

(22) Filed: Apr. 5, 2001

(51) Int. Cl. H05K 5/00

(52) U.S. Cl. 361/752

(57) ABSTRACT

A small form-factor pluggable metal cage has two sidewalls, a sidewall cover, a top plate, a soleplate and a rear cover, which are made of a single piece of metal plate. Two types of legs extend from the cage, one being needle eye legs for extending through holes defined in a printed circuit board and the other being piggy legs abutting against the board. The needle eye legs define a shape of ellipse with a slot therein,whereby the needle eye legs serve as broad locks preventing the cage from disengaging from the board during the course of reflowing, while the piggy legs serve as standoffs for separating the cage from the board.

### BACKGROUND OF THE INVENTION

1. Field of the Invention

The present invention relates to a small form-factor pluggable (SFP) optic transceiver module for fiber channel applications and, more particularly, to an optical transceiver module cage of high data transfer rate program GBIC.

2. The Related Art

Transceiver modules provide bi-directional transmission of data between an electrical interface and an optical data link. The module receives and converts electrically encoded data signals into optical signals which are then transmitted over the optical data link. Likewise, the module receives and converts optically encoded data signals into electrical signals and transmits the electrical signals in the electrical interface.

Normally, the transceiver module is mounted on a printed circuit board (PCB) assembly of a host computer, an input/output system, a peripheral device, or a switch. A small form-factor pluggable module connects with a metal cage assembly mounted on the PCB. The metal cage allows both ease of interconnection and ease of installation on PCB. The cage functions to dissipate electrostatics and serves as an electromagnetic shield.

The metal cage generally has two parallel sidewalls, a rectangular top, a rectangular bottom, and opposite ends. A conventional cage employs a two piece design. The two piece cage does not process a sufficient mechanical strength. Furthermore, the two piece design makes it difficult to manufacture and install the cage. In addition, the prior art cage forms legs for supporting the cage. However, no board locking mechanism is provided so that during the course of reflowing of a soldering process, the cage may inadvertently disengage from a PCB, causing poor soldering result.

### SUMMARY OF THE INVENTION

To solve the problems of the prior art, the present invention provides a small form-factor pluggable metal cage employing a one-piece design and the cage of the present invention has two types of legs. The first type is needle eye leg that can be assembled through a board. The second type is piggy leg which does not go through the board.

Accordingly, an object of the present invention is to provide a small form-factor pluggable metal cage having needle eye legs, each defining an shape of ellipsoid with a slot in the middle thereof for preventing the cage from disengaging from a printed circuit board (PCB) during the course of reflowing and stability on the PCB without solder.

It is further object of the present invention is to provide a small form-factor pluggable metal cage that enhances assembly.

It is another object of the present invention to provide a metal cage of an optical transceiver having a one-piece structure which provides excellent mechanical stability.

It is still another object of the present invention to provide a metal cage structure of a small form-factor pluggable which enhances automated production and thus reduces costs of production.

Other objects, advantages and novel features of the present invention will be apparent from the following detailed description of preferred embodiments thereof with reference to the attached drawings, in which:

### BRIEF DESCRIPTION OF THE DRAWINGS

FIG. 1 is a perspective view of an optical transceiver cage constructed in accordance with the present invention;

FIG. 2 is a perspective view of the optical transceiver cageof the present invention in a partially opened condition;

FIG. 3 is similar to FIG. 1 with a portion of the cage removed;

FIG. 4 is another perspective view of FIG. 2;

FIG. 5 is perspective view of Fig.1; and

FIG. 6 is an enlarged view of encircled portion VI of FIG. 5 showing legs of the cage of the present invention.

### DETAILED DESCRIPTION OF THE PREFERRED EMBODIMENTS

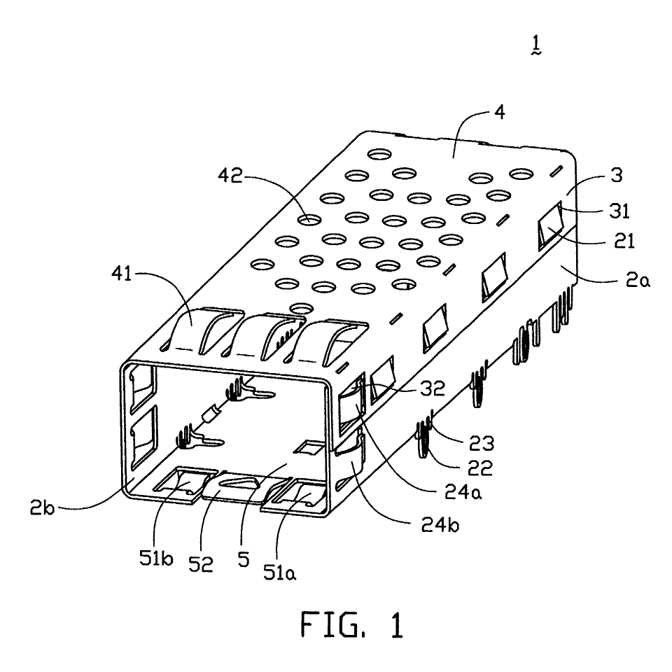

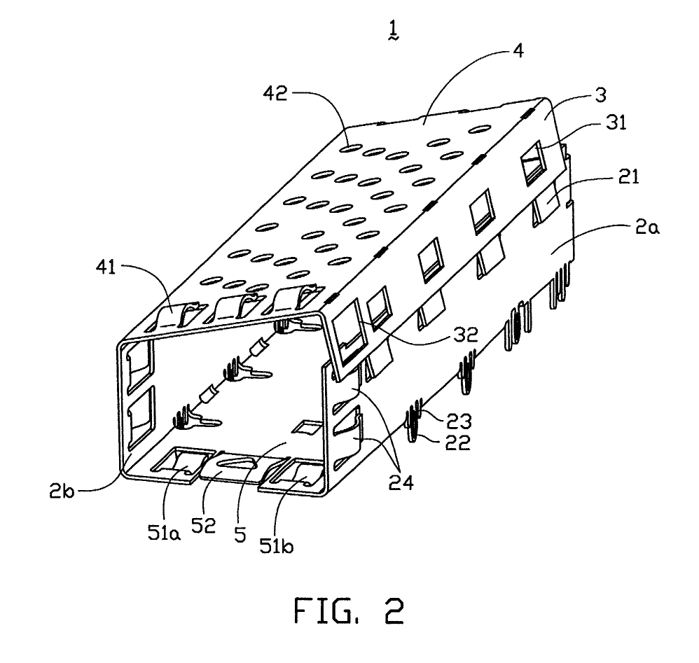

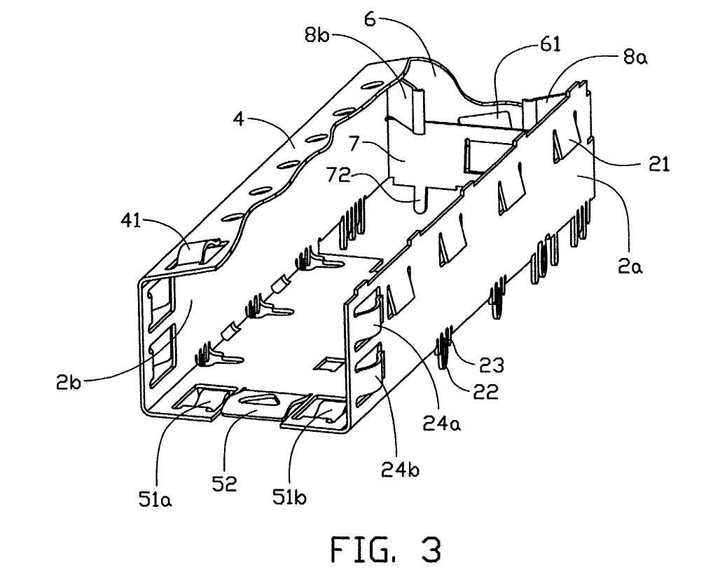

Referring to FIGS. 1-4, a small-form fact pluggable metal cage 1 in accordance with the present invention comprises a first sidewall 2a, a second sidewall 2b, a sidewall cover 3, a top plate 4, a soleplate 5, a rear cover including an outer panel 6 and an innerpanel 7 and two bulge patches 8a and 8b which are made of a single piece of blank material, such as a metal plate. The one-piece structure adds additional strength stability as compared with a prior art two piece metal cage.

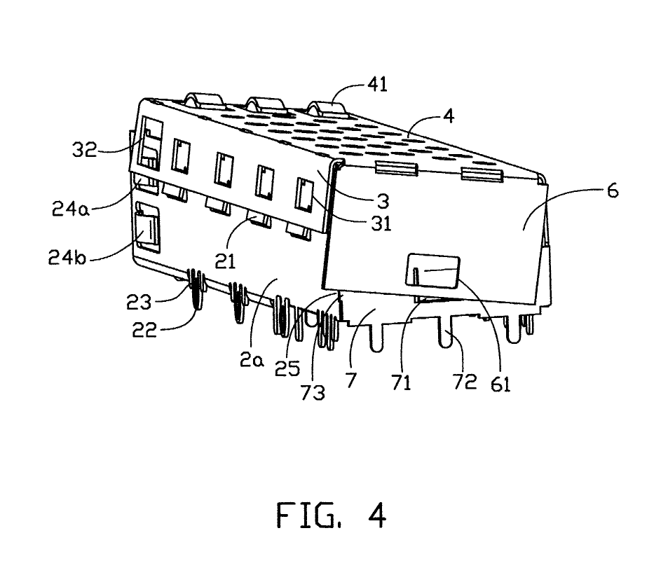

Each of the sidewalls 2a and 2b forms two grounding spring tabs 24a, 24b proximate a front end thereof and a plurality of needle eye legs 22 and piggy legs 23 at a lower edge thereof. The first sidewall 2a also forms a plurality of resilient clasps 21. A small notch 25 is defined in a rear edge of the first sidewall 2a (FIG. 4).

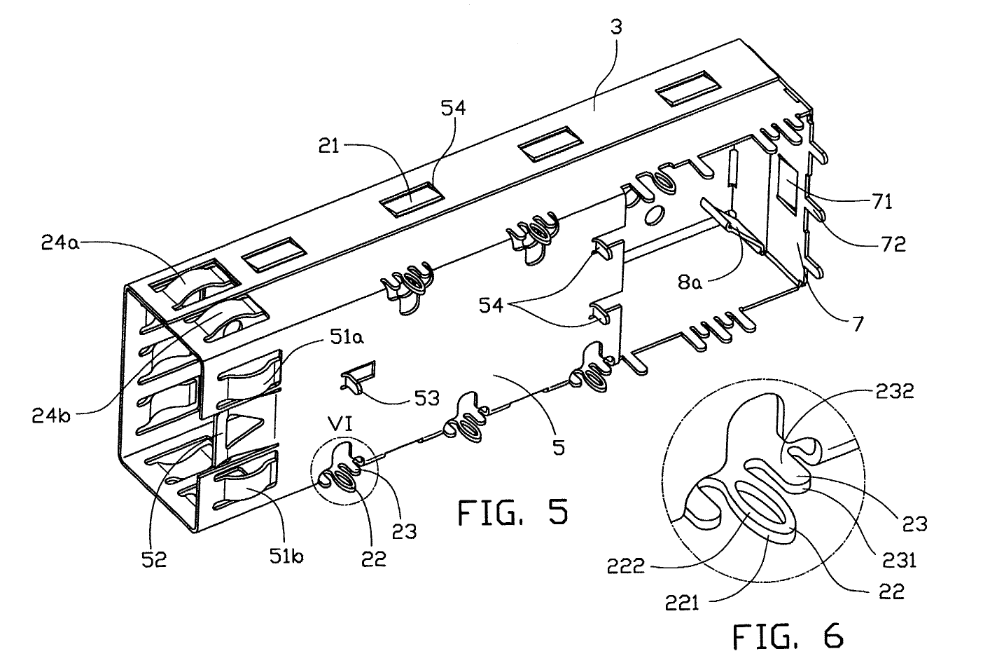

Also referring to FIGS. 5 and 6, in mounting the cage 1 to a printed circuit board (PCB, not shown), the needle eye legs 22 extend through corresponding holes defined in the board whereas the piggy legs 23 do not. Each piggy leg 23 comprises an elongate body 232 having a rounded end 231. Each needle eye leg 22 comprises a body 221 having a shape of ellipse 221 with a slot 222 defined in a middle portion thereof. A portion of the body 221 has a width larger than the diameter of the corresponding holes defined in the PCB, whereby the needle eye leg can be press-fit into the holes of the PCB for helping preventing the cage 1 from disengaging from the PCB during the course of reflowing. As a result, the cage 1 can be stably and firmly installed on the PCB without solder by means of the interference between the elliptical body 221 of the needle eye legs 22 and the corresponding holes of the PCB. At the same time, the needle eye structure allows the cage 1 to be easily disassembled from the PCB. In the embodiment illustrated in FIG. 5, three needle eye legs 22 are formed on each sidewall 2a, 2b and there are six needle eye legs 22 in total Furthermore, the needle eye legs 22 serve as broad locks securing the cage 1 on the board and the piggy legs 23 serve as standoff separating the cage 1 from the PCB for enhancing soldering. The two types of legs make the metal cage 1 easy to connect to and install on a PCB.

Turning back to FIGS. 1-4, the top plate 4 forms grounding spring tabs 41 at a front part thereof and defines a plurality of holes 42 at a rear portion. The sidewall cover 3 extends from the top plate 4 and overlapsthe first sidewall 2a. The sidewall cover 3 defines openings 31, 32 for engaging the clasps 21 and the grounding spring tab 24a of the first sidewall 2a, thereby securing the sidewall cover 3 to the first sidewall 2a,forming a parallelepiped cage.

The outer panel 6 of the rear cover extends from the top plate 4. A rectangular hole 61 is defined in the outer panel 6. The inner panel 7 extends from the second sidewall 2b and forms legs 72 extending from a lower edge thereof. The inner panel 7 forms a resilient clasp 71 engaging the rectangular hole 61 of the outer panel 6 and a projection 73 engaging the notch 25 of the first sidewall 2a to fix the innerpanel 7, the first sidewall 2a and the outer panel 6 together. Patches 8a and 8b respectively extend from the first sidewall 2a and the second sidewall 2b and are located above the inner panel 7.

Referring to FIG. 5, the soleplate 5 is shorter than thetop plate 4 and forms a central inward tab 52 and two grounding tabs 51a and 51b on opposite sides of the central tab 52. A central leg 53 proximate the tab 52 and two legs 54 at a rear edge of the soleplate 5 extend from the soleplate 5, also serving as standoffs.

1. A small form-factor pluggable transceiver cage comprising:
a top plate;
a soleplate;
a rear cover;
a sidewall cover;
two sidewalls; and
first and second legs extend out of a lower edge of each sidewall,the first legs being adapted to extend through a printed circuit board, and the second legs being adapted to abut against the printed circuit board.

2. The cage as described in claim 1, wherein at least one of the first legs has a body with a slot defined therein.

3. The cage as described in claim 2, wherein the body of the first leg has a portion having a width larger than a corresponding hole defined in the printed circuit board.

4. The cage as described in claim 2, wherein the cage is made of a single piece of metal plate.

5. The cage as described in claim 2, wherein the body of the first leg defines a shape of ellipse with a slot defined therein.

6. The cage as described in claim 5, wherein the elliptical body of the first leg has a portion having a width larger than a corresponding hole defined in the printed circuit body.

7. The cage as described in claim 5, wherein the cage is made of a single piece of metal plate.

8. A small form-factor pluggable transceiver cage comprising:
a top plate;
a soleplate;
a rear cover;
a sidewall cover;
two sidewalls, and the sidewalls comprising a plurality of needle eye legs having slots therein adapted to extend through a printed circuit board for causing mechanical interference between therebetween.

9. The cage as described in claim 8, wherein the needle eye legs have a portion having a width larger than corresponding holes defined in the printed circuit board.

10. The cage as described in claim 8, wherein at least one of the needle eye legs defines a shape of ellipse with the slot defined therein.

11. The cage as described in claim 8 further comprising piggy legs extending out of the sidewalls and being adapted to abut against the printed circuit board.

12. The cage as described in claim 11, wherein the needle eye legs have a portion having a width larger than corresponding holes defined in the printed circuit board.

13. The cage as described in claim 11, wherein at least one of the needle eye legs defines a shape of ellipse with the slot defined therein.

14. An electrical device cage comprising:
a soleplate;
first and second sidewalls respectively integrally extending upwardly and perpendicularly from two opposite side edges of the soleplate in a parallel relation with each other;
a top plate horizontally extending from a top edge of the first sidewall parallel to said soleplate;
a third sidewall downwardly and perpendicularly from a distal end of said top plate away from said first sidewall while at least partially overlapping said second sidewall; and
one of said third sidewall and said second sidewall defining a bulgy grounding tab, and the other of said third sidewall and said second sidewall defining an opening; wherein
said grounding tab extends through said opening to not only perform grounding similar to other grounding tabs surrounding a mating opening of said cage, but also interconnect said third sidewall and said second sidewall.

15. The cage as described in claim 14, wherein said third sidewall at least partially covers the second sidewall.

16. the cage as described in claim 15, wherein said grounding tab is formed on the second sidewall and the opening is formed in said third sidewall.
